(19) United States
(12) Patent Application Publication
(10) Pub. No.: US 2022/0059610 A1
(43) Pub. Date: Feb. 24, 2022

(54) LIGHT-EMITTING DIODE DEVICE AND DISPLAY INCLUDING THE SAME

(71) Applicant: XIAMEN SAN'AN OPTOELECTRONICS CO., LTD., Fujian Province (CN)

(72) Inventors: Su-Hui LIN, Xiamen (CN); Huining WANG, Xiamen (CN); Anhe HE, Xiamen (CN); Kang-Wei PENG, Xiamen (CN); Yu-Chieh HUANG, Xiamen (CN)

(21) Appl. No.: 17/401,495

(22) Filed: Aug. 13, 2021

(30) Foreign Application Priority Data
Aug. 20, 2020 (CN) 202010845753.8

(51) Int. Cl. H01L 27/15; H01L 33/20; H01L 33/54; H01L 33/62; H01L 33/38

(52) U.S. Cl. CPC H01L 27/156; H01L 33/20; H01L 33/38; H01L 33/62; H01L 33/54

(57) ABSTRACT

A light-emitting diode (LED) device includes multiple LED chips, a first protecting layer, and first and second electrical connection structures. The LED chips are separated from each other by a trench. Each LED chip is formed in a mesa structure, and includes first and second semiconductor layers and an active layer sandwiched therebetween. The first protecting layer covers a trench-defining wall of the trench, and the mesa structure of each LED chip. The first and second electrical connection structures penetrate through the first protecting layer to electrically and respectively connect in parallel with the first and second semiconductor layer of each LED chip.

### CROSS-REFERENCE TO RELATED APPLICATION

This application claims priority of Chinese Invention Patent Application No. 202010845753.8, filed on Aug. 20, 2020.

### FIELD

The disclosure relates to a semiconductor lighting device, and more particularly to a light-emitting diode device.

### BACKGROUND

As light-emitting diode (LED) technology advances, one of the research focuses is to develop LED chips of smaller size. Improvements in structural configuration, production, testing and assembly of small size LEDs are still challenging due to high production cost and difficulties in packaging, protection from damage, safe transportation, assembly and maintenance of such LED chips. Conventionally, small size LED chips are connected in series circuit to form high voltage LED device (such as a display). However, such high voltage LED device operating at high working voltage requires a higher power consumption and is liable to damage, which may incur safety concerns.

In addition, conventional LED chips are usually subjected to a full-line test for optoelectronic properties, such as forward bias voltage (VF), light output power (LOP), dominant wavelength (WLD) and reverse leakage current (IR). Measurements of these properties usually take a relatively long time (e.g., one-third to half of total testing time), which may result in a low test efficiency and reduction of production efficiency, especially for small size LED chips. For example, when a 4-inch wafer yields about 800,000 chips, and if each chip is tested using a conventional way, a total of about 30 hours of testing time is required, which seriously affects the production efficiency. In addition, when the size of the LED chips is further decreased to Z mil or below (1 mil=0.0254 mm, or 23.4 μm), or even in a micro scale, such testing would not be successfully conducted, as currently available test instrument which has test probes with a minimum diameter of 2.5 mil would cause the test probes to be positioned too close to each other (e.g., 30 μm or less), thereby causing circuit breaks during testing, resulting in damage to the test instrument.

Therefore, there is still a need to develop a LED device that is capable to operate under low voltage, and to overcome challenges in testing and packaging of small size LED chips.

### SUMMARY

Therefore, an object of the disclosure is to provide a light-emitting diode (LED) device and a display that can alleviate at least one of the drawbacks of the prior art.

According to the disclosure, the LED device includes a substrate, a plurality of LED chips, a first protecting layer, a first electrical connection structure and a second electrical connection structure. The substrate has a plurality of chip-forming regions. The LED chips are separated from each other by a trench that is defined by a trench-defining wall. Each of the LED chips is formed in a mesa structure and includes a first semiconductor layer, an active layer, a second semiconductor layer that are sequentially disposed on a corresponding one of the chip-forming regions of the substrate in such order. The first protecting layer covers the trench-defining wall of the trench, and the mesa structure of each of the LED chips. The first electrical connection structure is disposed on the first protecting layer opposite to the substrate, and penetrates through the first protecting layer to electrically connect in parallel with the first semiconductor layer of each of the LED chips. The second electrical connection structure is disposed on the first protecting layer opposite to the substrate, and penetrates through the first protecting layer to electrically connect in parallel with the second semiconductor layer of each of the LED chips.

According to the disclosure, the display includes at least one LED chip as mentioned above.

### BRIEF DESCRIPTION OF THE DRAWINGS

Other features and advantages of the disclosure will become apparent in the following detailed description of the embodiments with reference to the accompanying drawings, of which:

FIG. 1 is a top perspective view illustrating a first embodiment of a light-emitting diode (LED) device according to the disclosure;

FIG. 2 is a cross-sectional schematic view taken along line X-X′ in FIG. 1, illustrating the first embodiment of the LED device according to the disclosure;

FIG. 3 is a cross-sectional schematic view taken along line Y-Y′ in FIG. 1, illustrating the first embodiment of the LED device according to the disclosure;

FIG. 4 is a cross-sectional schematic view similar to FIG. 3, illustrating a variation of the first embodiment of the LED device according to the disclosure;

FIG. 5 is a cross-sectional schematic view similar to FIG. 3, illustrating another variation of the first embodiment of the LED device according to the disclosure;

FIG. 6 is a cross-sectional schematic view similar to FIG. 3, illustrating yet another variation of the first embodiment of the LED device according to the disclosure;

FIG. 7 is a cross-sectional schematic view similar to FIG. 3, illustrating still another variation of the first embodiment of the LED device according to the disclosure;

FIG. 8 is a top perspective view illustrating a second embodiment of the LED device according to the disclosure;

FIG. 9 is a cross-sectional schematic view taken along line V-V′ in FIG. 8, illustrating the second embodiment of the LED device according to the disclosure;

FIG. 10 is a cross-sectional schematic view similar to FIG. 9, illustrating a variation of the second embodiment of the LED device according to the disclosure;

FIG. 11 is a cross-sectional schematic view similar to FIG. 9, illustrating another variation of the second embodiment of the LED device according to the disclosure;

FIG. 12 is a cross-sectional schematic view similar to FIG. 9, illustrating yet another variation of the second embodiment of the LED device according to the disclosure;

FIGS. 13 to 15 are respectively a top schematic view illustrating different arrangements of the LED device according to the disclosure;

FIG. 16 is a top schematic view illustrating a backlight device according to the disclosure; and

FIG. 17 is a top schematic view illustrating a display according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

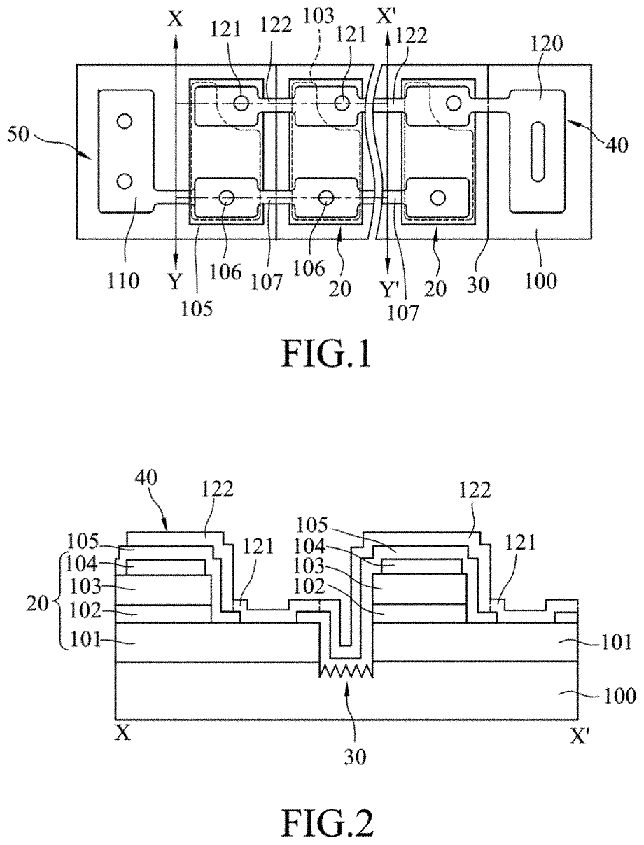

Referring to FIGS. 1 to 3, a first embodiment of a light-emitting diode (LED) device according to the disclosure includes a substrate 100, a plurality of LED chips 20 (only 3 LED chips are exemplarily shown in FIG. 1, but are not limited thereto), a first protecting layer 105, a first electrical connection structure 40 and a second electrical connection structure 50.

The substrate 100 may be made of a material including, but is not limited to, sapphire including aluminum oxide (Al₂O₃), silicon (Si), silicon carbide (SiC), aluminum nitride (AlN), gallium arsenide (GaAs) or any other suitable material.

The substrate 100 has a plurality of chip-forming regions, and each of the LED chips 20 is disposed on a corresponding one of the chip-forming regions. In certain embodiments, the substrate is a part of a wafer on which the LED chips 20 are first formed, and then the wafer is subjected to a dicing process to form a plurality of the LED devices of this disclosure, each of which may independently include a predetermined amount of the LED chips 20 according to practical needs. Each of the LED chips 20 is formed in a mesa structure, and has a length not greater than 250 μm. A projection of the mesa structure on the substrate 100 may be substantially a rectangle, or a square. Therefore, both the width and the length of the projection of the mesa structure may be not greater than 250 μm, such as 200 μm, or 100 μm, or 40 μm. In certain embodiments, the projection of each of the LED chips 20 on the substrate 100 may have an area ranging from 900 μm² to 62500 μm², such as 1600 μm² (40 μm×40 μm), or 62500 μm² (250 μm×250 μm), or 9677.4 μm² (3 mil×5 mil, i.e., 76.2 μm×127 μm). Two immediately adjacent ones of the LED chips 20 are spaced apart from each other by a distance ranging from 10 μm to 50 μm, for instance, 20 μm to 40 μm, or 30 μm. Controlling the size of the LED chips 20 and the distance therebetween may contribute to improvement in pitch (image resolution) and light-emitting effect of the LED device.

Each of the LED chips 20 includes a first semiconductor layer 101, an active layer 102, and a second semiconductor layer 103 that are sequentially disposed on the corresponding one of the chip-forming regions of the substrate 100 in such order. Each of the first and second semiconductor layers 101, 103 may be independently made of gallium nitride (GaN)-based material or aluminium gallium indium phosphide (AlGaInP)-based material. The first semiconductor layer 101 may be doped with an N-type dopant, and the second semiconductor layer 103 may be doped with a P-type dopant, or vice versa. Each of the first and second semiconductor layers 101, 103 may include sublayers with different functions. For instance, the first semiconductor layer 101 may include a GaN buffer sublayer, such as an unintentionally doped GaN buffer layer. The active layer 102 may be made of at least one nitride-based film that include indium (In). The active layer 102 may include an alternate stacking of a nitride film of narrow band gap and a nitride film of wide band gap. In certain embodiments, a bonding layer may be interposed between the first semiconductor layer 101 and the substrate 100.

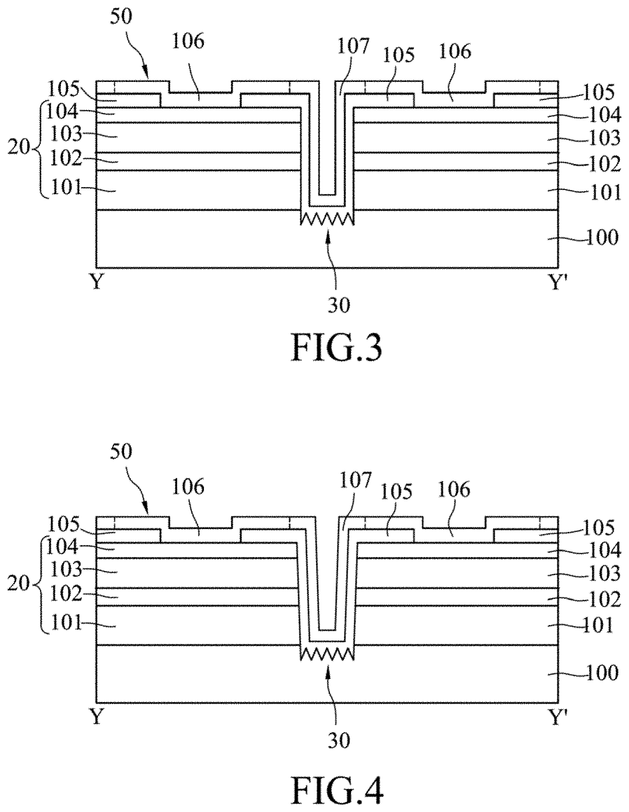

The LED chips 20 are separated from each other by a trench 30 that is defined by a trench-defining wall. That is, the chip-forming regions are defined by the trench 30. The trench-defining wall may have a depth not greater than 10 μm. The trench 30 may be formed by subjecting an epitaxial structure for forming the LED chips (i.e., the epitaxial structure including the first, semiconductor layer 101, the active layer 102 and the second semiconductor layer 103) to an etching process which may terminate at a predetermined position according to practical needs, as long as the trench 30 thus formed penetrates through the active layer 102 and the second semiconductor layer 103. That is, for each of the LED chips 20, the bottom surface of the trench defining wall of the trench 30 may be positioned at a level between the first semiconductor layer 101 and the substrate 100. In this embodiment, the trench 30 terminates at a contact surface between the first semiconductor layer 101 and the substrate 100, or even terminates at the substrate 100 (i.e., the substrate is over-etched) so as to expose a portion of the substrate 100. With such configuration, separation of the LED chips 20 (e.g., dicing process) may be easily performed. The bottom surface of the trench-defining wall may be a roughened surface as shown in FIGS. 2 and 3.

Alternatively, in other embodiments, the trench 30 may only terminate at the first semiconductor layer 101 without exposing the substrate 100, and the LED chips 20 are physically connected to each other through the first semiconductor layer 101. In such case, since the depth of the trench 30 is relatively small, other elements (e.g., the first and second electrical connection structures 40, 50 as described below) to be subsequently formed thereon may be less susceptible to fracture.

A lateral surface of the trench-defining wall angularly extends from the substrate 100 to an upper surface of the mesa structure opposite to the substrate 100. In the first embodiment, the lateral surface substantially perpendicularly extends from the substrate 100 (see FIGS. 2 and 3). In a variation of the first embodiment shown in FIG. 4, the lateral surface of the trench-defining wall non-perpendicularly extends from the substrate 100. An included angle between the lateral surface and the lower surface of the mesa structure may be, e.g., not greater than 60°. In certain embodiments, the included angle may range from 30√ to 55°, so as to form a relatively more gently inclined lateral surface which may facilitate formation of the first and second electrical connection structures 40, 50 that will be described in detail below. When the included angle is less than 30°, a light-emitting area of the LED chip may be undesirably reduced, and the size of the LED chip 20 may be difficult to decrease.

The first protecting layer 105 covers the trench-defining wall of the trench 30, and the mesa structure of each of the LED chips 20. The first protecting layer 105 may further cover other elements that are not mentioned above so as to provide more intact protection. The first protecting layer 105 may be made of silicon dioxide, silicon nitride, silicon oxynitride, or any combinations thereof.

The first electrical connection structure 40 is disposed on the first protecting layer 105 opposite to the substrate 100. The first electrical connection structure 40 includes a plurality of first electrodes 121 and a plurality of first bridging electrodes 122. As shown in FIGS. 1 and 2, each of the first, electrodes 121 penetrates through the first protecting layer 105 to electrically connect with the first semiconductor layer 101 of a respective one of the LED chips 20. That is, the first semiconductor layer 101 is exposed so as to connect with the first electrodes 121 of the first electrical connection structure 40. Each of the first bridging electrodes 122 is configured to interconnect two immediately adjacent ones of the first electrodes 121, and extends into the trench 30. That is, each of the first bridging electrodes 122 is formed on the bottom surface and the lateral surface of the trench 30. In certain embodiments, all of the first bridging electrodes 122 may be formed in one step, or may be formed separately in several steps. In certain embodiments, the first electrodes 121 and the first bridging electrodes 122 are formed as an integral structure. The LED chips 20 may be arranged in an array, and the first electrical connection structure 40 further includes an external electrode unit that includes a first external electrode 120 disposed at one terminal end of the array (see FIG. 1).

The second electrical connection structure 50 is disposed on the first protecting layer 105 opposite to the substrate 100. The second electrical connection structure 50 includes a plurality of second electrodes 106 and a plurality of second bridging electrodes 107. As shown in FIGS. 1 and 3, each of the second electrodes 106 penetrates through the first protecting layer 105 to electrically connect with the second semiconductor layer 103 of a respective one of the LED chips 20. Each of the second bridging electrodes 107 is configured to interconnect two immediately adjacent ones of the second electrodes 106, and extend into the trench 30. That is, each of the second bridging electrodes 107 is formed on the bottom surface and the lateral surface of the trench 30. All of the second bridging electrodes 107 may be formed in one step, or may be formed in several steps separately. In certain embodiments, the second electrodes 106 and the second bridging electrodes 107 are formed as an integral structure. The second electrical connection structure 50 further includes an external electrode unit that includes a second external electrode 110 disposed at another terminal end of the array opposite to the external electrode unit of the first electrical connection structure 40. As the LED chips 20 are electrically connected in parallel to each other, the external electrode unit of each of the of the first and second electrical connection structures 40, 50 may be disposed on at least one of the chip-forming regions (e.g., disposed across multiple chip-forming regions in certain embodiments), so as to facilitate testing of the LED chips 20.

Each of the first and second electrodes 121, 106, and the first and second bridging electrodes 122, 107 may be independently made of chromium (Cr), nickel (Ni), copper (Cu), silver (Ag), aluminum (Al), or combinations thereof.

Each of the LED chips 20 may further include a current spreading layer 104 that is disposed on the second semiconductor layer 103 opposite to the active layer 102. The current spreading layer 104 is covered by the first protecting layer 105, and is in contact with the second electrical connection structure 50 to electrically connect the second semiconductor layer 103 to the second electrical connection structure 50.

In a case that the LED chips 20 are flip-chip LED chips, the first protecting layer 105 may be formed with a distributed Bragg reflector (DBR) structure, and the current spreading layer 104 may serve as a transparent conductive layer that is made of indium tin oxide (ITO), zinc oxide (ZnO) or aluminum doped zinc oxide (AZO).

In a case that the LED chips 20 are face-up LED chips, the substrate 100 may be formed with a distributed Bragg reflector (DBR) structure. In certain embodiments, for each of the LED chips 20, each of the first and second electrical connection structures 40, 50 may be independently made of a material identical to that of the current spreading layer 104, which has an advantageous effect of reducing light emitted from the active layer 102 to be absorbed by the first and second electrical connection structures 40, 50. In such case, the first and second electrical connection structures 40, 50 are formed by a process same as that of the current spreading layer 104, so as to simplify the manufacturing process of the LED device.

In certain embodiments, the current spreading layer 104 may be omitted, and the first protecting layer 105 may be formed with a larger opening for the disposal of the second electrical connection structure 50. In this case, for each of the LED chips 20, each of the second electrodes 106 may have a larger contact area with the second semiconductor layer 103 so as to achieve improved current spreading effect. Such LED chips 20 may be more suitable for face-up packaging technique.

Since the LED chips 20 are electrically connected in parallel to each other through the first electrical connection structure 40 and the second electrical connection structure 50, the LED device of the disclosure may be conferred with advantageous characteristics in various aspects.

In one aspect, the LED device of the disclosure may be operated at a voltage that is relatively lower than that of a conventional high voltage LED device in which LED chips are electrically connected in series to each other, and thus the LED device of the disclosure is relatively safe, and exhibits a reduced power consumption.

In addition, with the abovementioned configuration, the size of the LED chips 20 and the distance therebetween can be further reduced (e.g., not greater than 250 μm, or 1 mil to 3 mil), so as to facilitate testing of the LED device. Since the LED chips 20 that are electrically connected in parallel to each other in ay have similar optoelectronic properties, testing of the LED chips 20 may be performed on a portion of the LED chips and an averaged value of the tested portion of LED chips can be used to determine the overall quality of the LED device, instead of testing the LED chips 20 one by one. In one example, forward bias voltage for each of the LED chips 20 within the same array of the LED chips 20 is the same, such that only one of the LED chips 20 is required to be subjected to forward bias voltage measurement. In another example, when one row of the array of LED chip 20 having a reverse leakage current (IR) value which is determined to be larger than a predetermined threshold value, such row of the LED chips 20 may be considered defective. As such, testing time may be greatly reduced and testing efficiency may be improved. In addition, the external electrode units of the first and second electrical connection structures 40, 50 may serve as testing electrodes, or as connection electrodes connected to an external power source.

In another aspect, as the LED chips 20 may foe directly transferred to a packaging substrate to foe packaged as an integral structure, packaging efficiency and yield may be increased. The dicing process may foe performed to produce separated LED devices each having corresponding amount of LED chips 20. For example, one of the resultant LED devices may have one LED chip 20, and the other one of the resultant LED devices may have more than one LED chips 20. As compared to LED chips that are electrically connected in series to each other, the LED chips 20 that are electrically connected in parallel to each other cars foe easily prepared without customizing or changing the configuration of each LED chip 20.

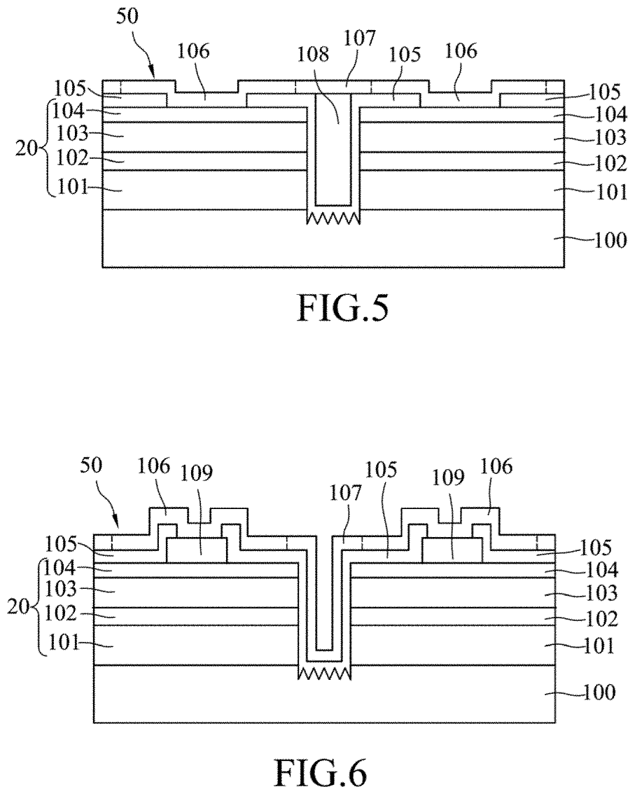

Referring to FIG. 5, the LED device of another variation of the first embodiment is generally similar to the first embodiment, except that the another variation further includes a second protecting layer 108 that partially or entirely fills a portion of the trench 30 which is covered by the first protecting layer 105. The second protecting layer 108 may be made of a material identical to or different from that of the first protecting layer 105. In addition, for the first electrical connection structure 40, each of the first bridging electrodes 122 is disposed on the second protecting layer 108 to interconnect two immediately adjacent ones of the first electrodes 121 (not shown in figures). For the second electrical connection structure 50, each of the second bridging electrodes 107 is disposed on the second protecting layer 108 to interconnect two immediately adjacent ones of the second electrodes 106. In a case that the trench 30 is entirely filled with the second protecting layer 108 (i.e., the second protecting layer 108 flushes with the first protecting layer 105 without height difference), the first and second bridging electrodes 122, 107 can be disposed on a flat surface that is cooperatively formed by the first and second protecting layers 105, 103, so that strength and electrical properties of the first and second bridging electrodes 122, 107 may be increased, thereby improving reliability of the LED device of this disclosure.

Referring to FIG. 6, in yet another variation of the first embodiment which is similar to the first embodiment shown in FIG. 3, each of the LSD chips 20 further includes a contact electrode 109 that is disposed on the current spreading layer 104 opposite to the second semiconductor layer 103. The contact electrode 109 is partially covered by the first protecting layer 105, and is in contact with the second electrode 106 of second electrical connection structure 50 to electrically connect the current spreading layer 104 to the second electrode 106. The contact electrode 109 is capable of lowering a contact resistance between the current spreading layer 104 and the second electrodes 106. In addition, the contact electrode 109 may also be disposed to be in contact with the first electrodes 121, so that the first electrical connecting structure 40 is electrically connected to the current spreading layer 104 (not shown in figures), thereby further enhancing the electrical properties of the LED device.

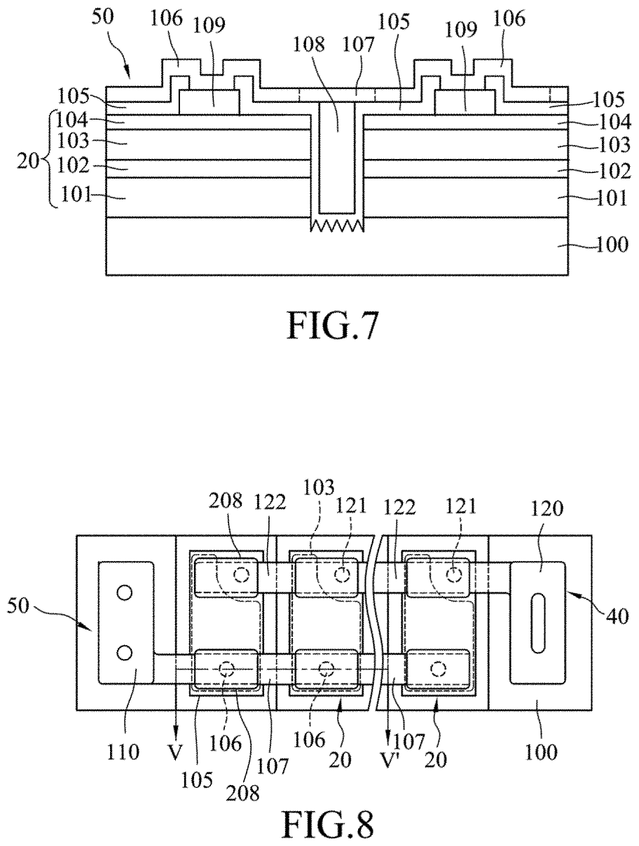

Referring to FIG. 7, a still yet another variation of the first embodiment of the LED device is generally similar to the aforementioned yet another variation shown in FIG, 6, except that the still yet another variation further includes the second protecting layer 108 as described for the variation shown in FIG. 5, and the details thereof are omitted herein for sake of brevity. Such configuration is conducive to connecting the LED chips 20 to top electrodes when the LED chips 20 are packaged as flip-chip structures.

Production of the LED devices of the abovementioned variations (as shown in FIGS. 5 to 7) is relatively simpler than that of the first embodiment, (as shown in FIGS. 1 to 3). For example, there may be no need to manufacture a current blocking layer, external electrodes, etc., thereby simplifying the manufacturing process of the LED device.

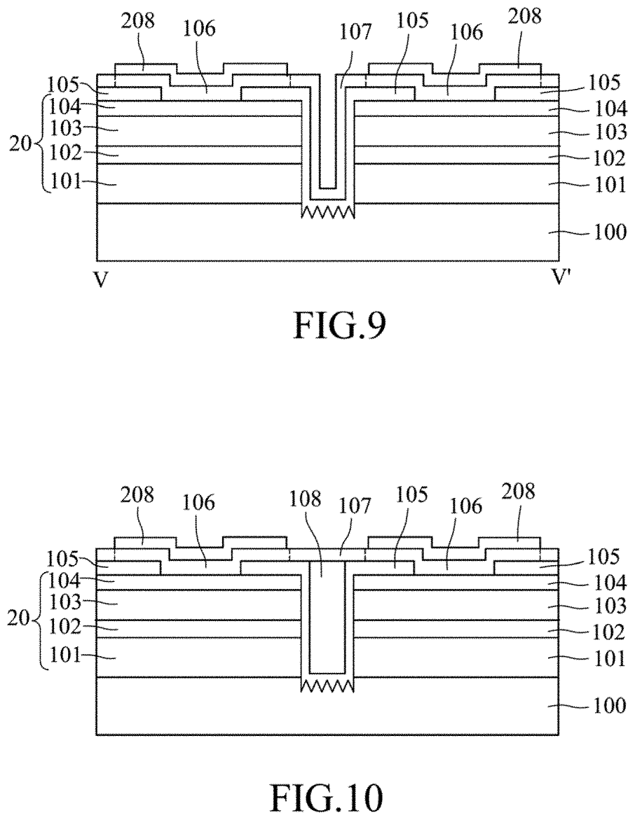

Referring to FIGS. 8 and 9, a second embodiment of the LED device is similar to the first embodiment, except that the second embodiment further includes a plurality of top electrodes 208. Each of the top electrodes 208 are independently disposed on the second electrical connection structure 50 and the first electrical connection structure 40 opposite to the mesa structure of a respective one of the LED chips 20. In certain embodiments, each of the top electrodes 208 may serve as a bonding pad for packaging the LED chips 20 as flip-chip structures by directly attaching each of the top electrodes 208 onto a packaging substrate (not shown in figures). The top electrodes 208 may also improve heat-dissipating of the LED chips 20.

Referring to FIG. 10, similar to the description for the LED device shown in FIG. 5, in a variation of the second embodiment, the second protecting layer 108 is further included to fill a portion of the trench 30 which is covered by the first protecting layer 105.

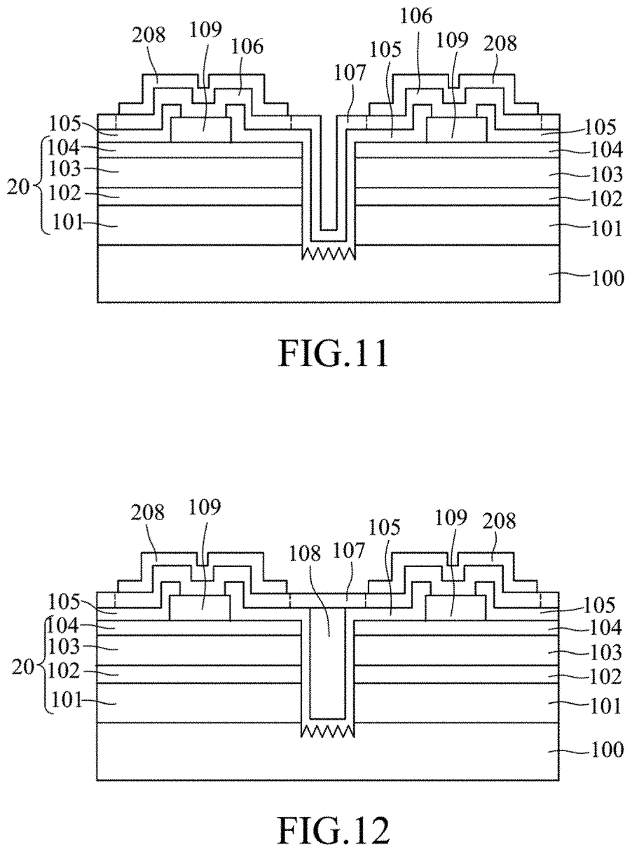

Referring to FIG. 11, similar to the description for the LED device shown in FIG. 6, in another variation of the second embodiment, for each of the LED chips 20, the contact electrode 109 is further disposed on the current spreading layer 104 opposite to the second semiconductor layer 103.

Referring to FIG. 12, similar to the description for the LED device shown in FIG. 7, in yet another variation of the second embodiment, the second protecting layer 108 and the contact electrode 109 are both included.

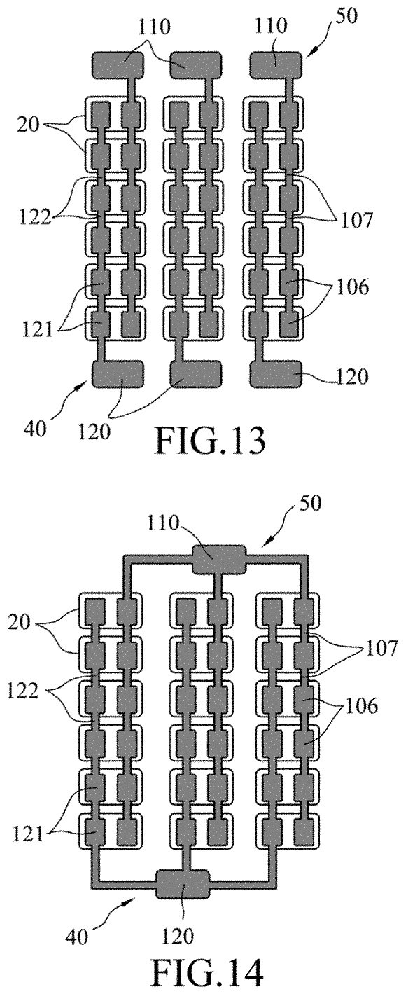

Referring back to FIGS. 1 and 8, for each of the LED device described in the first embodiment and the second embodiment, the LED chips 20 are arranged in an array that includes a single row. The array of the LED chips 20 in the LED device may have different arrangements, such as multiple rows. The number of the LED chips 20 in each row and the number of rows in the array may be adjusted according to practical needs. FIGS. 13 to 15 illustrate several different arrangements of the LED chips 20, in which three rows each having six LED chips 20 are illustrated, but are not limited thereto.

Specifically, referring to FIG. 13, each of the three rows of the LED chips 20 is independent from the other two rows of the LED chips 20, and for each of the rows, each of the LED chips 20 are connected in parallel to each other. For the second connection structure 50, the external electrode unit may include a plurality of second external electrodes 110, each of which is disposed at one terminal end of a respective one of the rows of the LED chips 20. For the first connection structure 40, the external electrode unit may include a plurality of first external electrodes 120, each of which is disposed at another terminal end of the respective one of the rows of the LED chips 20 opposite to the second electrical connection structure 50.

Each of the external electrode unit of the first and second electrical connection structures 40, 50 is disposed on one of the chip-forming regions of the substrate 100. Alternatively, each of the external electrode unit of the first and second electrical connection structures 40, 50 may be disposed across more than one of the chip-forming regions of the substrate 100, in particular when the LED chips 20 have relatively small size, e.g., in micro scale.

Referring to FIG. 14, each of the rows of the LED chips 20 is electrically connected to each other in parallel (i.e., the arrangement differs from that shown in FIG. 13), and for each of the rows, each of the LED chips 20 are connected in parallel to each other, so as to form a ceil structure. The first electrical connection structure 40 includes one first external electrode 120 that is electrically connected in parallel to the rows of the LED chips 20. In such case, the first electrical connection structure 40 may be configured as a first comb structure with the first external electrode 120 serving as a comb body and each row of the first electrodes 121 and the first bridging electrodes 122 cooperatively serving as a teeth portion. In addition, the second electrical connection structure 50 includes one second external electrode 110 that is electrically connected in parallel to the rows of the LED chips 20. The second electrical connection structure 50 may be configured as a second comb structure with the second external electrode 110 serving as a comb body, and each row of the second electrodes 106 and the second bridging electrodes 107 cooperatively serving as a teeth portion. The teeth portions of the first and second comb structures 40, 50 intersperse with each other.

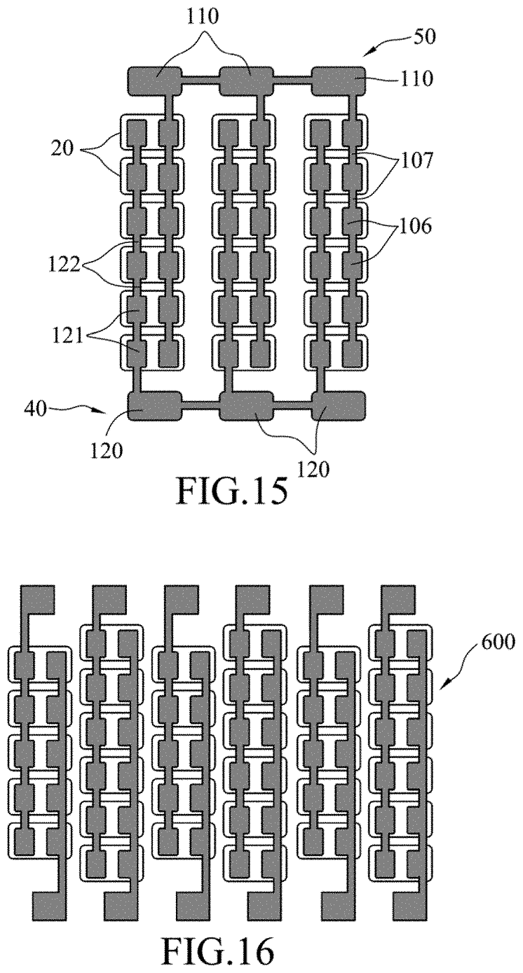

Referring to FIG. 15, the three first external electrodes 120 of the first electrical connection structure 40 are electrically connected to each other, and the three second external electrodes 110 of the second electrical connection structure 50 are electrically connected to each other (i.e., this arrangement differs from the arrangement shown in FIG. 13). Such arrangement of the LED chips 20 allows testing to be easily performed on any one of the first external electrodes 120 and any one of second external electrodes 110.

Referring to FIG. 16, the LED device according to the disclosure may be applied as a backlight device 600. The LED chips 20 are arranged into multiple rows (for instance, but is not limited to, six rows, each row including five to six LED chips 20). For each row, the LED chips 20 are electrically connected to each other in parallel. Each row of the LED chips 20 is independent from another row of the LED chips 20. As such, the backlight device 600 may be operated at a relatively low voltage with improved light-emitting efficiency.

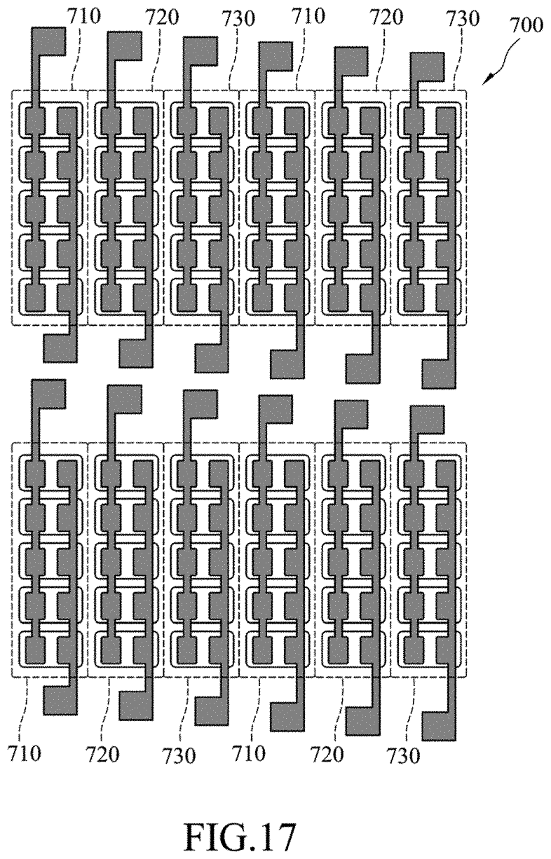

Referring to FIG. 17, a display 700 of this disclosure includes at least one LED device as mentioned above. In an exemplary embodiment, the display 700 is a RGB display, and includes a plurality of first LED devices 710 emitting light of a first color (e.g., blue light), a plurality of second LED devices 720 emitting light of a second color (e.g., green light), and a plurality of third LED devices 730 emitting light of a third color (e.g., red light). The first and second external electrodes 120, 110 may be disposed at predetermined locations to readily connect with an external power source (not shown in figures). In addition, each of the LED chips 20 may be formed as a single pixel independent display unit by, e.g., further connecting each of the first and second bridging electrodes 122, 107 thereof to a switching structure such as a thin film transistor.

To prepare the abovementioned display 700, a plurality of LED devices are first uniformly formed in an array, and then the LED devices are covered with different fluorescent films or wavelength converting layers in such a manner that the first LED devices 710, the second LED devices 720, and the third LED devices 730 emitting specific colors are obtained. For example, the first LED devices emitting blue color may be usually not covered with the fluorescent films, and each of the second LED devices 720 emitting green light may be covered with a first type of the fluorescent films and the third LED devices 730 emitting red light may be covered with a second type of the fluorescent films. Since the first, second and third LED devices 710, 720, 730 are to be arranged and aligned in different rows, covering the fluorescent films can be conducted in a row-by-row manner, instead of one-by-one manner. Therefore, the display 700 may be manufactured with improved efficiency and reduced manufacturing cost, and may exhibit improved light-emitting efficiency. The display 700 also possesses advantages such as long service life, high intensity, small volume, lower power consumption and high pixel density, etc., and thus the display 700 can be desirably applied in various light-emitting appliances such as computer monitors, phone monitors, wearable devices, or even large size display screen.

To conclude, by inclusion of the first electrical connection structure 40 and the second electrical connection structure 50 that cooperate to allow the LED chips 20 to be connected in parallel to each other, the LED device according to the disclosure can be operated at a low working voltage, thereby solving safety issues during operation and reduces power consumption. In addition, the arrangement of the LED chips 20 on the LED device according to the disclosure may facilitate optoelectronic tests without damaging testing instrument.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A light-emitting diode (LED) device, comprising:
a substrate having a plurality of chip-forming regions;
a plurality of LED chips which are separated from each other by a trench that is defined by a trench-defining wall, each of said LED chips being formed in a mesa structure and including a first semiconductor layer, an active layer, and a second semiconductor layer that are sequentially disposed on a corresponding one of said chip-forming regions of said substrate in such order;
a first protecting layer which covers said trench-defining wall of said trench, and said mesa structure of each of said LED chips;
a first electrical connection structure which is disposed on said first protecting layer opposite to said substrate and which penetrates through said first protecting layer to electrically connect in parallel with said first semiconductor layer of each of said LED chips; and
a second electrical connection structure which is disposed on said first protecting layer opposite to said substrate and which penetrates through said first protecting layer to electrically connect in parallel with said second semiconductor layer of each of said LED chips.

2. The LED device of claim 1, wherein each of said LED chips further includes a current spreading layer disposed on said second semiconductor layer opposite to said active layer, said current spreading layer being covered by said first protecting layer and being in contact with said second electrical connection structure to electrically connect said second semiconductor layer to said second electrical connection structure.

3. The LED device of claim 2, wherein for each of said LED chips, said second electrical connection structure is made of a material identical to that of said current spreading layer.

4. The LED device of claim 3, further comprising a plurality of top electrodes, each of said top electrodes being independently disposed on said second electrical connection structure opposite to said mesa structure of a respective one of said LED chips.

5. The LED device of claim 1, wherein said first electrical connection structure includes a plurality of first electrodes and a plurality of first bridging electrodes, each of said first electrodes penetrating through said first protecting layer to electrically connect with said first semiconductor layer of a respective one of said LED chips, each of said first bridging electrodes being configured to interconnect two immediately adjacent ones of said first electrodes, and extending into said trench.

6. The LED device of claim 1, wherein said second electrical connection structure includes a plurality of second electrodes and a plurality of second bridging electrodes, each of said second electrodes penetrating through said first protecting layer to electrically connect with said second semiconductor layer of a respective one of said LED chips, each of said second bridging electrodes being configured to interconnect two immediately adjacent ones of said second electrodes, and extending into said trench.

7. The LED device of claim 1, further comprising a second protecting layer that fills a portion of said trench covered by said first protecting layer, said first electrical connection structure including a plurality of first electrodes and a plurality of first bridging electrodes, each of said first electrodes penetrating through said first protecting layer to electrically connect with said first semiconductor layer of a respective one of said LED chips, and each of said first bridging electrodes being disposed on said second protecting layer to interconnect two immediately adjacent ones of said first electrodes.

8. The LED device of claim 1, further comprising a second protecting layer that fills a portion of said trench covered by said first protecting layer, said second electrical connection structure including a plurality of second electrodes and a plurality of second bridging electrodes, each of said second electrodes penetrating through said first protecting layer to electrically connect with said second semiconductor layer of a respective one of said LED chips, and each of said second bridging electrodes being disposed on said second protecting layer to interconnect two immediately adjacent ones of said second electrodes.

9. The LED device of claim 2, wherein each of said LED chips further includes a contact electrode that is disposed on said current spreading layer opposite to said second semiconductor layer, said contact electrode being partially covered by said first protecting layer, and being in contact with said second electrical connection structure to electrically connect said current spreading layer to said second electrical structure.

10. The LED device of claim 1, wherein said LED chips are arranged in an array, and said second electrical connection structure includes an external electrode unit disposed at one terminal end of said array.

11. The LED device of claim 10, wherein said first electrical connection structure includes an external electrode unit disposed at another terminal end of said array opposite to said external electrode unit of said second electrical connection structure.

12. The LED device of claim 10, wherein said array has multiple rows, one row of said LED chips being independent from another row of said LED chips, and said external electrode unit of said second electrical structure including a plurality of second external electrodes, each of which is disposed at one terminal end of a respective one of said rows of said LED chips.

13. The LED device of claim 10, wherein said array has multiple rows, and said external electrode unit including at least one second external electrode that is electrically connected in parallel to said rows of said LED chips.

14. The LED device of claim 10, wherein said external electrode unit is disposed on at least one of said chip-forming regions of said substrate.

15. The LED device of claim 1, wherein a projection of each of said LED chips on said substrate has an area ranging from 900 μm to 6250 μm².

16. The LED device of claim 15, wherein two immediately adjacent ones of said LED chips are spaced apart from each other by a distance ranging from 10 μm to 50 μm.

17. The LED device of claim 1, wherein for each of said LED chips, said trench-defining wall has a lateral surface angularly extending from said substrate to an upper surface of said mesa structure opposite to said substrate, an included angle between said lateral surface and said lower surface of said mesa structure is not greater than 60°.

18. The LED device of claim 1, wherein for each of said LED chips, a bottom surface of said trench-defining wall is positioned at a level between said first, semiconductor layer and said substrate.

19. The LED device of claim 1, wherein said trench-defining wall has a depth not greater than 10 μm.

20. A display, comprising at least one LED device as claimed in claim 1.
